(19) United States
(12) Patent Application Publication
(10) Pub. No.: US 2026/0118559 A1
(43) Pub. Date: Apr. 30, 2026

(54) WIDE COVERAGE DIFFUSING LENS AND WIDE COVERAGE LIGHT-EMITTING DRIVE PACKAGE

(71) Applicant: Global Technologies Co., LTD, Hwaseong-si Gyeonggi-do (KR)

(72) Inventors: Min Seon KIM, Hwaseong-si Gyeonggi-do (KR); Seung Hyun OH, Gwangju-si Gyeonggi-do (KR); Jung Hyun PARK, Osan-si Gyeonggi-do (KR)

(73) Assignee: Global Technologies Co., LTD, Hwaseong-si Gyeonggi-do (KR)

(21) Appl. No.: 19/370,048

(22) Filed: Oct. 27, 2025

(30) Foreign Application Priority Data
Oct. 30, 2024 (KR) 10-2024-0151423

(51) Int. Cl. G02B 3/08; H01L 25/16; H10H 29/24; H10H 29/855

(52) U.S. Cl. CPC G02B 3/08; H10H 29/855; H10H 29/24; H10W 90/00

(57) ABSTRACT

The present disclosure relates to a wide coverage diffusing lens and a wide coverage light-emitting drive package having a wide light irradiation area. The wide coverage diffusing lens comprises an incident surface adapted to receive light generated from a light-emitting device; and an exit surface adapted to refract or reflect the light incident from the incident surface and emit the light to a widely diffused area. The exit surface may comprise a central column portion formed with an overall cylindrical shape; and at least one rim dome portion formed around a periphery of the central column portion, wherein at least a portion of the at least one rim dome portion is formed in a dome shape or a hemispherical shape.

### CROSS-REFERENCE TO RELATED PATENT APPLICATION

The present application claims priority under 35 U.S.C. § 119 (a) to Korean Patent Application No. 10-2024-0151423, filed in the Korean Intellectual Property Office on Oct. 30, 2024, which application is incorporated herein by reference in its entirety.

### BACKGROUND

### 1. Field of the Disclosure

The present disclosure relates to a wide coverage diffusing lens and a wide coverage light-emitting drive package, and more particularly, to a wide coverage diffusing lens and a wide coverage light-emitting drive package having a wide light irradiation area.

### 2. Description of the Related Art

Generally, conventional light-emitting device packages are formed by mounting one light-emitting device (LED) on a substrate and molding the same with a molding member, and when such single-focus light-emitting device packages are used in backlight units, light irradiation areas are narrow, so separate optical lenses capable of refracting or diffusing light on optical paths have been attached to solve this problem.

Such optical lenses were also formed in very simple convex lens shapes and often failed to reflect characteristics of light-emitting devices, which caused many problems such as low conversion efficiency and light being transmitted only to narrow areas.

In particular, when such optical lenses are used in multi-focus light-emitting device packages in which a plurality of light-emitting devices are formed, there were many problems such as dark areas being partially generated so that light quantities become non-uniform overall or luminous efficiency is reduced.

In addition, when a plurality of lenses are applied to multi-focus light-emitting device packages, the number of components and production processes are increased so that product costs and productivity are significantly reduced, and light loss due to diffusing and refraction occurs at interfaces of optical lenses so that optical efficiency is very low. When configuring backlights, focal distances become longer so that required optical distances (OD) are increased, which causes backlight unit thickness to become thicker, or when configuring backlight units of the same area, the number of required light-emitting device packages is significantly increased, and it becomes difficult to achieve optical uniformity, causing many problems.

In addition, backlight units using such conventional light-emitting device packages are configured such that separate driver elements such as driver ICs for driving the light-emitting device packages are mounted on printed circuit boards in addition to the light-emitting device packages, and since wiring layers of the printed circuit boards become very complicated, wiring layers must be configured in multiple layers, which increases circuit complexity of the printed circuit boards so that manufacturing costs of the printed circuit boards are increased. Furthermore, the number of components such as driver elements is increased so that product costs and manufacturing process costs such as bonding are significantly increased, and many problems occur such as emission angle deviations due to positional deviations during assembly of the above-described optical lenses.

Meanwhile, backlight units using conventional light-emitting device packages have problems in that light-emitting devices and driver elements are mounted on one printed circuit board on the same plane, which causes packages or circuit configurations to become large or have large areas, thereby increasing raw material costs.

### SUMMARY OF THE DISCLOSURE

A wide coverage diffusing lens according to the present disclosure for solving the above objects comprises an incident surface on which light generated from a light-emitting device is incident, and an exit surface that refracts or reflects the light incident from the incident surface to emit the light to a wide diffused area. The exit surface comprises a central column portion formed in a cylindrical shape, and at least one rim dome portion formed around a perimeter of the central column portion, the rim dome portion having at least a portion formed in a dome shape or hemispherical shape.

Meanwhile, a wide coverage light-emitting drive package according to the present disclosure for solving the above objects comprises a substrate; a terminal layer formed on one surface of the substrate; a wiring layer formed on another surface of the substrate and electrically connected to the terminal layer via a through-electrode; at least one light-emitting device mounted on a portion of the wiring layer and disposed at an outer position of the substrate; a driver IC mounted on another portion of the wiring layer, disposed at a central position of the substrate, and adapted to drive the light-emitting device; and a wide coverage diffusing lens adapted to diffuse light generated from the light-emitting device. The wide coverage diffusing lens comprises an incident surface on which light generated from the light-emitting device is incident, and an exit surface adapted to refract or reflect the light incident from the incident surface and emit the light to a wide diffused area. The exit surface comprises a central column portion formed in a cylindrical shape, and at least one rim dome portion formed around a perimeter of the central column portion, wherein at least a portion of the rim dome portion is formed in a dome shape or hemispherical shape.

### BRIEF DESCRIPTION OF THE DRAWINGS

The above and other features and advantages of the present disclosure will become more apparent by describing in detail embodiments thereof with reference to the attached drawings in which:

FIG. 1 is a perspective view illustrating a wide coverage diffusing lens according to some embodiments of the present disclosure.

FIG. 2 is a plan view of the wide coverage diffusing lens of FIG. 1.

FIG. 3 is a bottom view of the wide coverage diffusing lens of FIG. 1.

FIG. 4 is a cross-sectional view illustrating the IV-IV cross-section of the wide coverage diffusing lens of FIG. 1.

FIG. 5 is a perspective view illustrating a wide coverage diffusing lens according to some other embodiments of the present disclosure.

FIG. 6 is a plan view of the wide coverage diffusing lens of FIG. 5.

FIG. 7 is a perspective view illustrating a wide coverage diffusing lens according to some further embodiments of the present disclosure.

FIG. 8 is a plan view of the wide coverage diffusing lens of FIG. 7.

FIG. 9 is an exploded perspective view illustrating a wide coverage light-emitting drive package having the wide coverage diffusing lens of FIG. 1 according to some embodiments of the present disclosure.

FIG. 10 is a bottom view illustrating the wide coverage light-emitting drive package of FIG. 9.

FIG. 11 is a plan view illustrating the wide coverage light-emitting drive package of FIG. 9.

FIG. 12 is a cross-sectional view illustrating the wide coverage light-emitting drive package of FIG. 9.

FIG. 13 is a plan view illustrating a light irradiation area of the wide coverage light-emitting drive package of FIG. 9.

FIG. 14 is a plan view illustrating a backlight unit according to some embodiments of the present disclosure.

FIG. 15 is a plan view illustrating a display apparatus according to some embodiments of the present disclosure.

FIG. 16 is an exploded perspective view illustrating a wide coverage light-emitting drive package according to some other embodiments of the present disclosure.

FIG. 17 is a plan view illustrating the wide coverage light-emitting drive package of FIG. 16.

FIG. 18 is a cross-sectional view illustrating the wide coverage light-emitting drive package of FIG. 16.

### DETAILED DESCRIPTION OF THE DISCLOSURE

Hereinafter, various preferred embodiments of the present disclosure will be described in detail with reference to the accompanying drawings.

The embodiments of the present disclosure are provided to more completely describe the present disclosure to those skilled in the art. The following embodiments may be modified in various different forms, and the scope of the present disclosure is not limited to the following embodiments. Rather, these embodiments are provided to make the present disclosure more faithful and complete, and to completely convey the spirit of the present disclosure to those skilled in the art. In addition, the thickness or size of each layer in the drawings is exaggerated for convenience and clarity of description.

Throughout this specification, when one component such as a layer, region, or substrate is referred to as being positioned “on,” “connected to,” “stacked on,” or “coupled to” another component, it may be interpreted that the one component directly contacts “on,” “connected to,” “stacked on,” or “coupled to,” the other component or that intervening components may be present therebetween. On the other hand, when one component is referred to as being positioned “directly on,” “directly connected to,” or “directly coupled to” another component, it is interpreted that no intervening components exist therebetween. Like reference numerals refer to like elements. As used herein, the term “and/or” includes any one and all combinations of one or more of the associated listed items.

In this specification, terms such as “first,” “second,” and the like are used to describe various members, components, regions, layers and/or portions, but it should be understood that these members, components, regions, layers and/or portions should not be limited by these terms. These terms are used only to distinguish one member, component, region, layer, or portion from another region, layer, or portion. Therefore, a first member, component, region, layer, or portion discussed below could be referred to as a second member, component, region, layer, or portion without departing from the teachings of the present disclosure.

The present disclosure is directed to solving various problems including the above-described problems, and an object of the present disclosure is to provide a wide coverage diffusing lens and a wide coverage light-emitting drive package that can configure multi-focus packages in which a plurality of micro-LEDs are disposed around a driver IC so that optical uniformity can be improved by preventing dark areas, high light output and wide emission angles can be achieved, product costs can be reduced by reducing the number of components, and productivity can be significantly improved. However, these objects are exemplary, and the scope of the present disclosure is not limited thereby.

According to an embodiment of the present disclosure, a multi-focus package having a plurality of micro-LEDs disposed around a driver IC can be constructed, thereby preventing dark regions to improve optical uniformity, achieving high light output and wide emission angles, reducing component count to lower product cost and manufacturing expenses, significantly enhancing productivity, minimizing the circuit complexity of printed circuit boards when applied to backlight units, expanding light irradiation areas to substantially reduce the required number of components and optical efficiency demands, reducing product thickness, and enabling component integration wherein molding members function as lenses to prevent component variations and emission angle deviations. The scope of the present disclosure is not, however, limited to these advantageous effects.

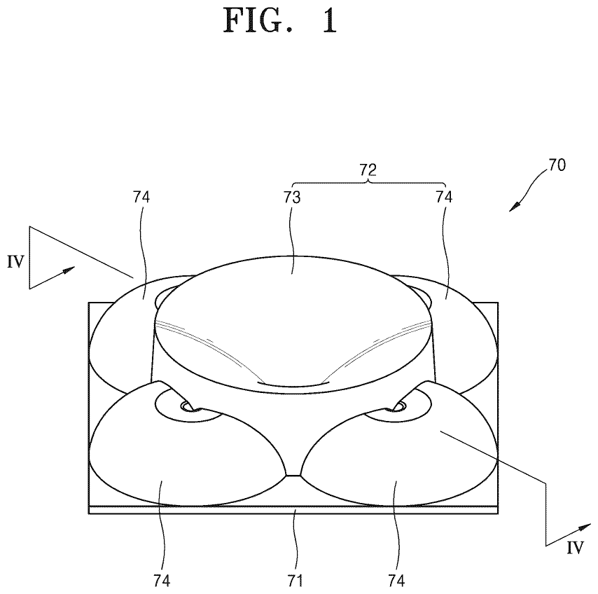

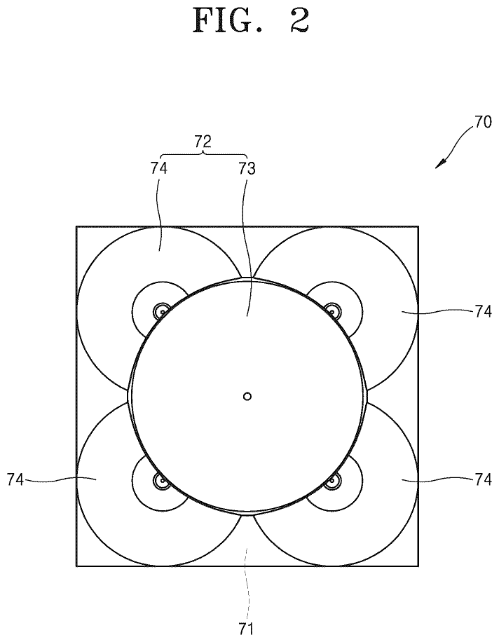

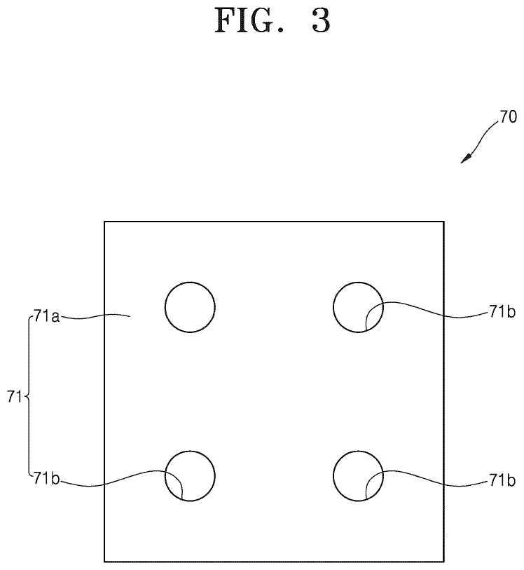

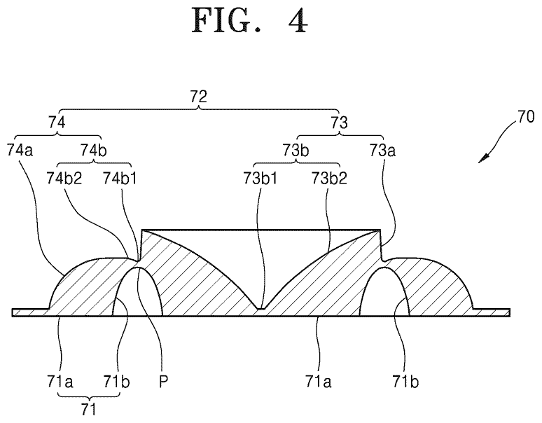

FIG. 1 is a perspective view showing a wide coverage diffusing lens 70 according to some embodiments of the present disclosure, FIG. 2 is a plan view of the wide coverage diffusing lens 70 of FIG. 1, FIG. 3 is a bottom view of the wide coverage diffusing lens 70 of FIG. 1, and FIG. 4 is a cross-sectional view taken along line IV-IV of the wide coverage diffusing lens 70 of FIG. 1.

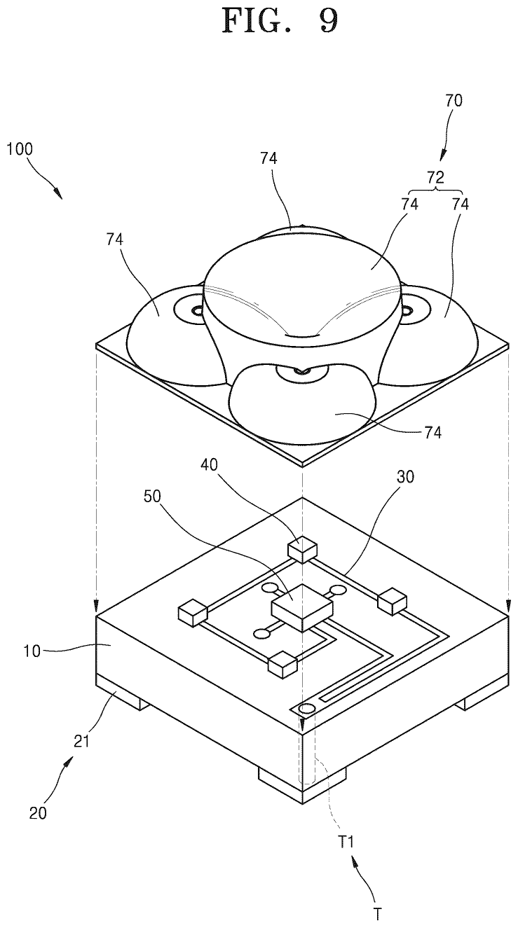

As shown in FIGS. 1 to 4, the wide coverage diffusing lens 70 according to some embodiments of the present disclosure may include an incident surface 71 adapted to receive light generated from a light-emitting device 40 (see FIG. 9) and an exit surface 72 adapted to refract or reflect the light incident from the incident surface 71 and emit the light to a widely diffused area.

Here, the incident surface 71 and the exit surface 72 may be, for example, both surfaces of a lens forming one body, and various light-transmissive materials such as transparent EMC, CMC (Clear Molding Compound Epoxy), silicone, epoxy, silicon oxide, glass, quartz, ceramic, polycarbonate, and the like may all be applied.

First, the incident surface 71 may include, for example, as shown in FIGS. 3 and 4, a bottom portion 71a formed in an overall flat shape and an incident groove portion 71b formed concavely in the bottom portion 71a so as to correspond to the light-emitting device 40 and formed in an overall dome shape toward an apex P.

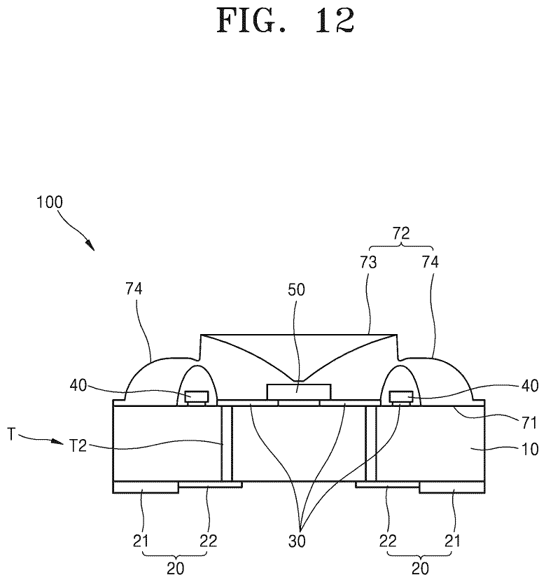

Therefore, at least a portion of the light-emitting device 40 (see FIG. 12) may be inserted into the incident groove portion 71b, or the incident groove portion 71b may be disposed on an optical path of the light-emitting device 40 so that light generated from the light-emitting device 40 can be incident.

Here, the wide coverage diffusing lens 70 according to some embodiments of the present disclosure may have four rim dome portions 74 formed around a periphery of one central column portion 73 so as to correspond to four light-emitting devices 40 and allow light to be dispersed to an overall rectangular area. For example, as shown in FIG. 3, a total of four incident groove portions 71b may be formed in the bottom portion 71a.

The exit surface 72 may include, for example, as shown in FIGS. 1 to 4, one central column portion 73 formed with an overall cylindrical shape and four rim dome portions 74 formed integrally with the central column portion 73 and formed at least one or more around a periphery of the central column portion 73, wherein at least a portion is formed in a dome shape or a hemispherical shape.

The central column portion 73 is formed with an overall cylindrical shape, for example, as shown in FIG. 4, and may have an outer peripheral surface 73a formed on a side surface and a central concave groove portion 73b formed on a top surface.

The central concave groove portion 73b may include, for example, as shown in FIG. 4, a central bottom point portion 73b1 formed concavely on a central axis and a central convex inclined surface portion 73b2 formed in an overall funnel shape slanted toward the central bottom point portion 73b1 and having a cross-section formed convexly upward.

The rim dome portion 74 may have, for example, as shown in FIG. 4, a spherical surface 74a formed on at least a portion of a side surface, and a rim concave groove portion 74b formed concavely on the outer peripheral surface 73a of the central column portion 73 or on a top surface adjacent to the outer peripheral surface 73a.

The rim concave groove portion 74b may include, more specifically for example, a rim bottom point portion 74b1 formed on a top surface and a rim convex inclined surface portion 74b2 formed in an overall funnel shape slanted toward the rim bottom point portion 74b1 and having a cross-section formed convexly upward.

Accordingly, as illustrated in FIGS. 1 to 4, describing the light diffusing process of the wide coverage diffusing lens 70 according to some embodiments of the present disclosure, light generated from four light-emitting devices 40 is incident through the incident surface 71, refracted and reflected by the incident groove portion 71b such that a portion of the light can be diffused extensively over a wide range to peripheral portions of the light irradiation area through the rim dome portions 74 of the exit surface 72, and another portion of the light can be diffused extensively over a wide range to central portions where dark regions might otherwise be formed, by being refracted or reflected by the rim concave groove portions 74b through the outer peripheral surface 73a of the central column portion 73.

Therefore, when configuring a multi-focus package having a plurality of light-emitting devices 40 such as four light-emitting devices, light can be diffused in a wide range toward four corner directions respectively using the four rim dome portions 74, and simultaneously, dark portions between the light-emitting devices 40 can be eliminated using the central column portion 73, thereby achieving overall uniform and high luminous intensity and a wide directional angle.

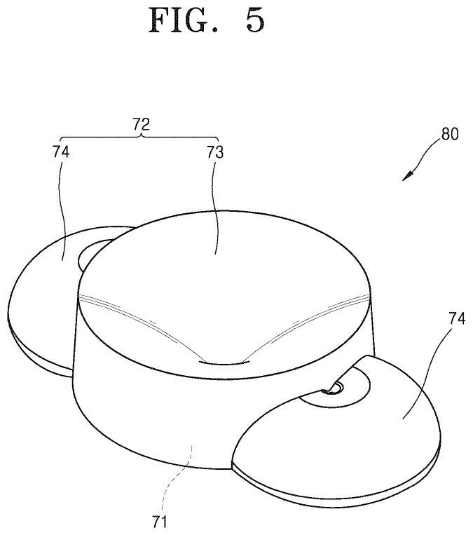

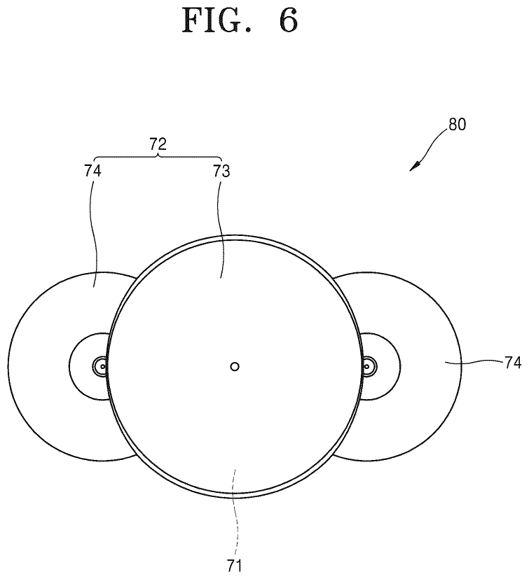

FIG. 5 is a perspective view showing a wide coverage diffusing lens 80 according to some other embodiments of the present disclosure, and FIG. 6 is a plan view of the wide coverage diffusing lens 80 of FIG. 5.

As shown in FIGS. 5 and 6, the wide coverage diffusing lens 80 according to some other embodiments of the present disclosure may have two rim dome portions 74 formed around a periphery of one central column portion 73 so as to correspond to two light-emitting devices 40 and allow light to be dispersed to an overall linear area.

Therefore, as shown in FIGS. 5 and 6, the light diffusing process of the wide coverage diffusing lens 80 according to some other embodiments of the present disclosure can be described as follows: light generated from the two light-emitting devices 40 is incident through the incident surface 71, and a portion of the light can be diffused in a wide range to rim portions of a light irradiation area through the rim dome portion 74 of the exit surface 72, and another portion of the light can be diffused in a wide range to central portions between the two light-emitting devices 40 where dark areas might otherwise be formed, by being refracted or reflected by the central column portion 73.

Therefore, when configuring a multi-focus package having a plurality of light-emitting devices 40 such as two light-emitting devices, light can be diffused in a wide range toward two corner directions respectively using the two rim dome portions 74, and simultaneously, dark portions between the light-emitting devices 40 can be eliminated using the central column portion 73, thereby achieving overall uniform and high luminous intensity and a wide directional angle.

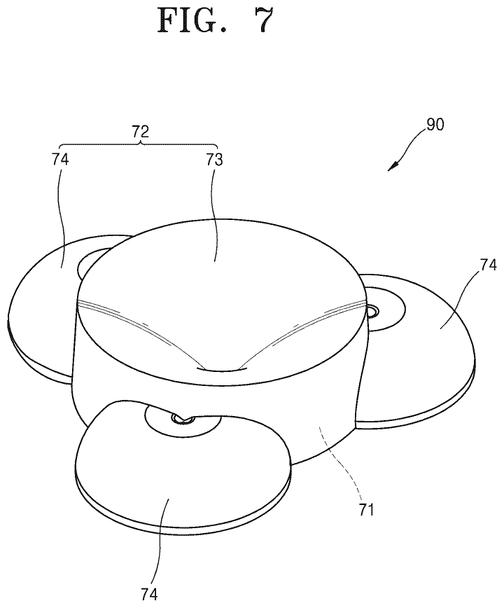

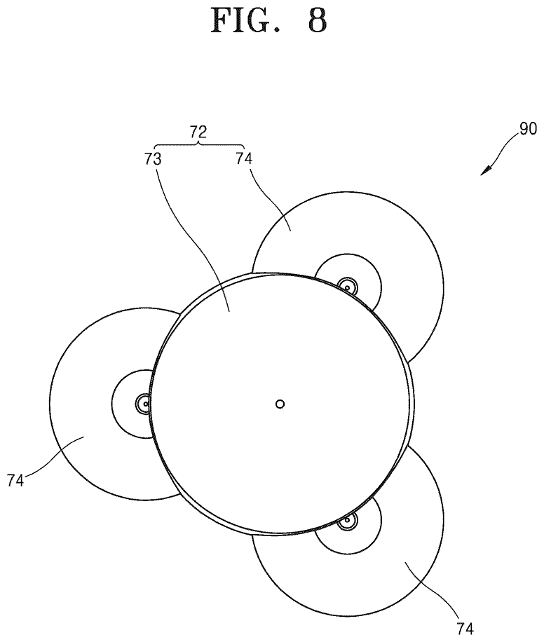

FIG. 7 is a perspective view showing a wide coverage diffusing lens 90 according to some further embodiments of the present disclosure, and FIG. 8 is a plan view of the wide coverage diffusing lens 90 of FIG. 7.

As shown in FIGS. 7 and 8, the wide coverage diffusing lens 90 according to some further embodiments of the present disclosure may have three rim dome portions 74 formed around a periphery of one central column portion 73 so as to correspond to three light-emitting devices 40 and allow light to be dispersed to an overall triangular area.

Therefore, as shown in FIGS. 7 and 8, the light diffusing process of the wide coverage diffusing lens 90 according to some further embodiments of the present disclosure can be described as follows: light generated from the three light-emitting devices 40 is incident through the incident surface 71, and a portion of the light can be diffused in a wide range to rim portions of a light irradiation area through the rim dome portion 74 of the exit surface 72, and another portion of the light can be diffused in a wide range to central portions among the three light-emitting devices 40 where dark areas might otherwise be formed, by being refracted or reflected by the central column portion 73.

Therefore, when configuring a multi-focus package having a plurality of light-emitting devices 40 such as three light-emitting devices, light can be diffused in a wide range toward three corner directions respectively using the three rim dome portions 74, and simultaneously, dark portions between the light-emitting devices 40 can be eliminated using the central column portion 73, thereby achieving overall uniform and high luminous intensity and a wide directional angle.

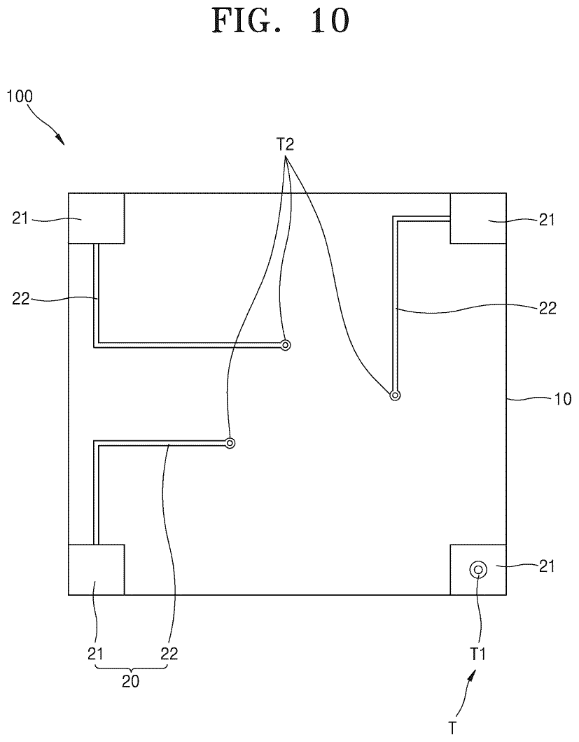

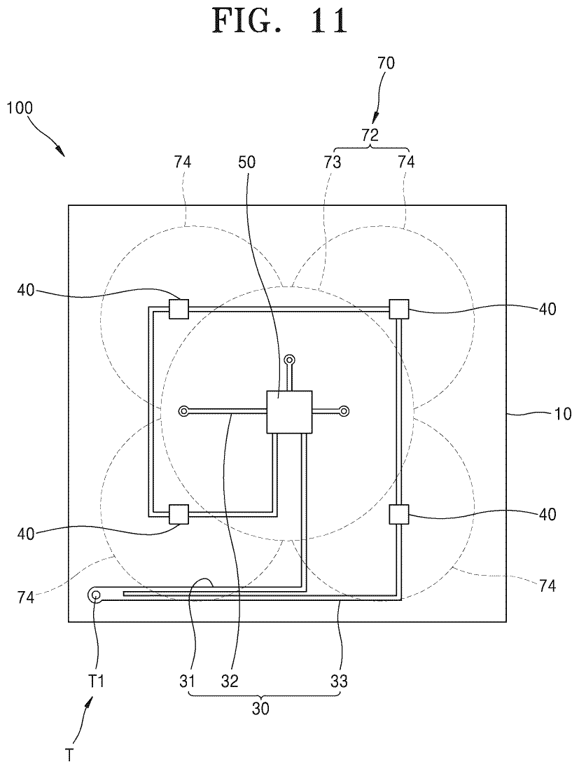

FIG. 9 is an exploded perspective view showing a wide coverage light-emitting drive package 100 having the wide coverage diffusing lens 70 of FIG. 1 according to some embodiments of the present disclosure, FIG. 10 is a bottom view showing the wide coverage light-emitting drive package 100 of FIG. 9, FIG. 11 is a plan view showing the wide coverage light-emitting drive package 100 of FIG. 9, and FIG. 12 is a cross-sectional view showing the wide coverage light-emitting drive package 100 of FIG. 9.

As shown in FIGS. 9 to 12, the wide coverage light-emitting drive package 100 according to some embodiments of the present disclosure may include largely a substrate 10, a terminal layer 20, a wiring layer 30, light-emitting devices 40, a driver IC 50, and a wide coverage diffusing lens 70.

The substrate 10 is, for example, formed of at least partially insulating material, and may be a substrate or board such as a printed circuit board formed of single layer or multiple layers, a ceramic substrate, or a metal substrate, and may be a plate-shaped structure having sufficient strength and durability so as to support the light-emitting devices 40, the driver IC 50, and protective members 60.

However, the substrate 10 is not necessarily limited to the drawings, and may be formed in various three-dimensional shapes depending on specifications, types, or shapes of packages.

The terminal layer 20 may be, for example, a type of conductive layer formed on one surface of the substrate 10, namely a bottom surface.

The terminal layer 20 may be, more specifically for example, as shown in FIG. 2, a conductive layer including pad portions 21 such as a power terminal (Vdd), a ground terminal (Vss), a digital input terminal (Din), a digital output terminal (Dout), and the like formed at outer edge portions of a bottom surface of the substrate 10, and extension portions 22 extending from the pad portions 21 so as to fade in toward a central portion of the bottom surface of the substrate 10.

However, the form and type of the terminal layer 20 are not necessarily limited to the drawings, and various other forms and types of terminal layers may all be applied.

The wiring layer 30 may be, for example, a conductive layer formed on the other surface of the substrate 10, namely a top surface, and electrically connected to the terminal layer 20 using through-electrodes T.

The wiring layer 30 may include, more specifically for example, as shown in FIG. 11, a first wiring portion 31 having one portion electrically connected to a pad through-electrode T1 formed at a ground terminal (Vss) among the pad portions 21 and another portion connected to the driver IC 50, a second wiring portion 32 having one portion electrically connected to extension through-electrodes T2 respectively formed at a power terminal (Vdd), a digital input terminal (Din), and a digital output terminal (Dout) formed at the extension portion 22 and another portion connected to the driver IC 50, and a third wiring portion 33 having one portion connected to the driver IC 50, another portion connected to a plurality of light-emitting devices 40, and still another portion electrically connected to the pad through-electrode T1.

Here, the third wiring portion 33 may be formed in an overall spiral shape with an angular or curved form where a range gradually becomes wider so as to extend from the driver IC 50 through all of the light-emitting devices 40 to the pad through-electrode T1 to improve integration density of the package.

However, the form and type of the wiring layer 30 are not necessarily limited to the drawings, and various other forms and types of terminal layers may all be applied.

In addition, although not shown, the wide coverage light-emitting drive package 100 according to some embodiments of the present disclosure may further include an underfill member filled between the substrate 10 and the light-emitting devices 40 or between the substrate 10 and the driver IC 50, a conductive adhesive member applied on the wiring layer 30, and the like.

The light-emitting devices 40 are light output elements mounted on portions of the wiring layer 30 and disposed at outer positions of the substrate 10. More specifically for example, the light-emitting devices 40 may be micro-LEDs or mini-LEDs adapted to form backlight illumination by including at least one or more of red LEDs, green LEDs, blue LEDs, white LEDs, and combinations thereof, or adapted to form one display pixel with red LEDs, green LEDs, and blue LEDs.

The light-emitting devices 40 may be, for example, Light Emitting Diodes (LEDs) in a flip chip form having first pads and second pads formed on bottom surfaces. However, the light-emitting devices 40 are not necessarily limited to the flip chip form, and LEDs including various colored inorganic light-emitting chips in a non-flip form having pads formed on top surfaces may also be applied. These light-emitting devices 40 may be conventional LEDs as well as all forms of LEDs such as mini-LEDs or micro-LEDs.

In addition, light-emitting devices to which bonding wires are applied to terminals, or to which bonding wires are applied only to first terminals or second terminals partially, or horizontal type and vertical type light-emitting devices may all be applied, but a flip chip form may be preferable to implement miniaturization and ultra-thinning of products.

The driver IC 50 is mounted on other portions of the wiring layer 30, disposed at a central position of the substrate 10, and may be a driver IC of one channel or more adapted to drive the light-emitting devices 40.

The driver IC 50 may include, more specifically for example, at least one Display Driving Integrated Circuit (DDIC).

That is, the driver IC 50 may be driving components such as a driver IC of one channel or more electrically connected to the light-emitting devices 40 and adapted to drive the light-emitting devices 40.

The driver IC 50 includes driving circuits therein, and the driving circuits may be formed with various types of circuits adapted to supply power to the light-emitting devices 40, control driving voltages, process feedback signals, control driving brightness of the light-emitting devices 40, or correct light output of the light-emitting devices 40 according to reference light output of other light-emitting devices.

Here, a plurality of the light-emitting devices 40 may be symmetrically disposed along diagonal or cruciform patterns centered around the driver IC 50 to achieve wide coverage of optical paths, for example, as shown in FIGS. 9 to 12.

More specifically for example, the light-emitting devices 40 may be two or more LEDs (four in the drawings) respectively disposed in front left, front right, rear left, and rear right directions around the driver IC 50, as shown in FIG. 11. However, the arrangement of the light-emitting devices 40 is not necessarily limited to the drawings, and although not shown, it is also possible that the light-emitting devices 40 are two or more LEDs respectively disposed in front, rear, left, and right directions around the driver IC 50.

The wide coverage diffusing lens 70 may be a type of optical member adapted to diffuse light generated from the light-emitting devices 40.

The wide coverage diffusing lens 70 may include, more specifically for example, at least one or more light-transmissive components or light-converting components among silicone, epoxy, phosphor layers, quantum dots, light-transmissive materials, and combinations thereof that are assembled or molded on the wiring layer 30.

Here, the configuration and role of the wide coverage diffusing lens 70 may be the same as those of the wide coverage diffusing lens 70 of the present disclosure as described above in FIGS. 1 to 8. Therefore, detailed description thereof will be omitted.

Therefore, when power signals, ground signals, digital input signals, and the like are input through the terminal layer 20 formed on the bottom surface of the substrate 10, the electrical signals are transmitted to the wiring layer 30 formed on the top surface of the substrate 10 through the through-electrodes T, and these input signals may first be input to the driver IC 50.

Subsequently, driving signals from the driver IC 50 are applied to the four light-emitting devices 40 through the wiring layer 30 in response to the input signals, emitted to a wide area by multi-focus light sources, and digital output signals may be output through the wiring layer 30, the through-electrodes T, and the terminal layer 20.

At this time, light generated from the light-emitting devices 40 can be uniformly diffused to a wide area through the wide coverage diffusing lens 70 while simultaneously preventing formation of dark areas, thereby significantly improving optical uniformity.

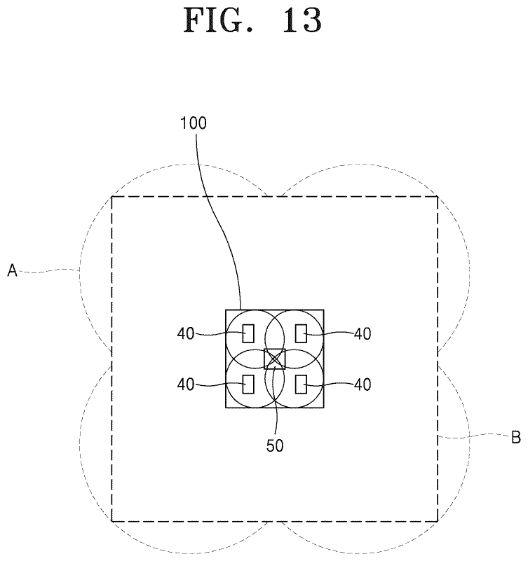

FIG. 13 is a plan view showing a light irradiation area A of the wide coverage light-emitting drive package 100 of FIG. 9.

As shown in FIG. 13, since the light irradiation area A of the wide coverage light-emitting drive package 100 according to some embodiments of the present disclosure can sufficiently cover a backlight coverage area B, sufficient backlight effects can be obtained with only the wide coverage light-emitting drive package 100 while reducing thickness of one backlight unit, and additionally, circuit complexity of printed circuit boards can be minimized when applying backlight units, light irradiation areas are widened so that optical efficiency can be increased and required number of components can be significantly reduced, and components such as wide coverage diffusing lenses are integrated so that component variations or emission angle deviations can be prevented.

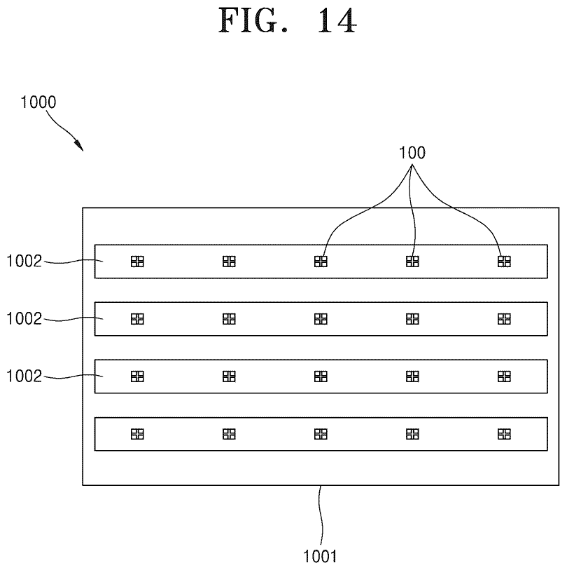

FIG. 14 is a plan view showing a backlight unit 1000 according to some embodiments of the present disclosure.

As shown in FIG. 14, the backlight unit 1000 according to some embodiments of the present disclosure can be formed by mounting the above-described wide coverage light-emitting drive package 100 on a bar-type or fork-type printed circuit board 1002 formed inside a rectangular frame 1001.

Therefore, the backlight unit 1000 of the present disclosure can minimize circuit complexity of the printed circuit board 1002, light irradiation areas are widened so that optical efficiency can be increased and required number of components can be significantly reduced, and components are integrated such that molding members serve as lenses so that component variations or emission angle deviations can be prevented.

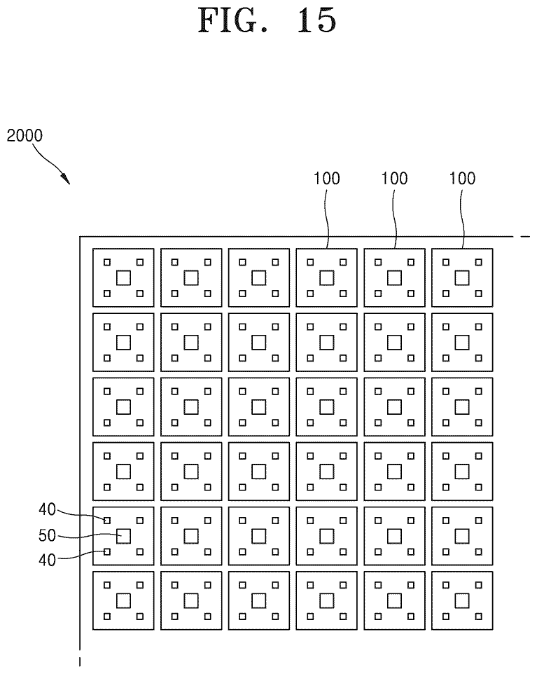

FIG. 15 is a plan view showing a display apparatus 2000 according to some embodiments of the present disclosure.

As shown in FIG. 15, the display apparatus 2000 according to some embodiments of the present disclosure may be formed by arranging a plurality of the above-described wide coverage light-emitting drive packages 100 in M rows and N columns to form pixels and overall constitute a display screen.

Therefore, the display apparatus 2000 of the present disclosure has good visibility due to wide viewing angles, does not require additional driver ICs and the like, so that the number of components and the number of processes can be reduced to decrease product costs, and productivity can be significantly improved.

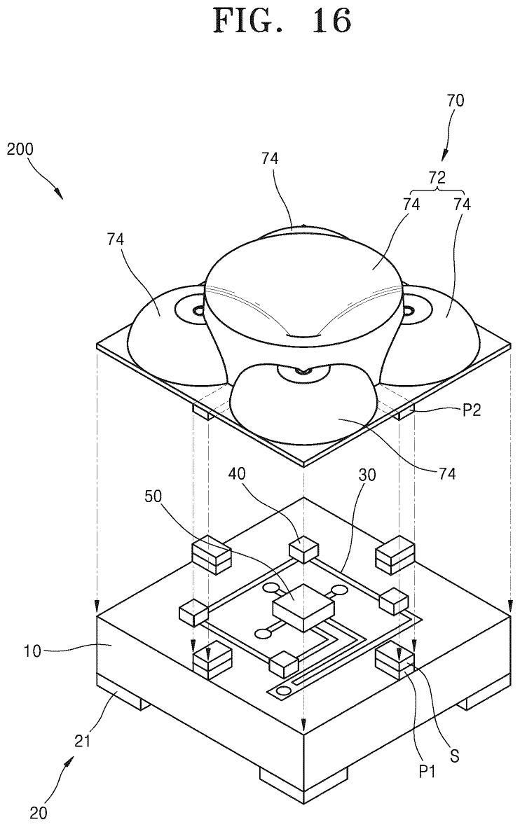

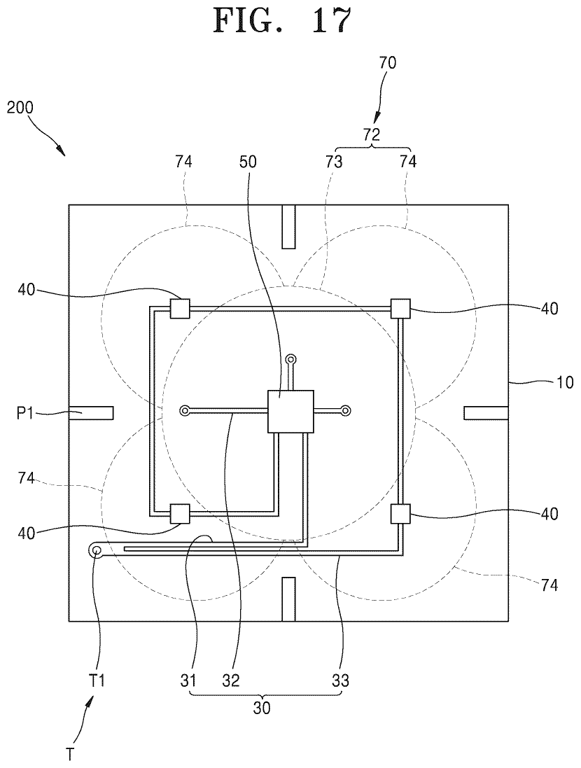

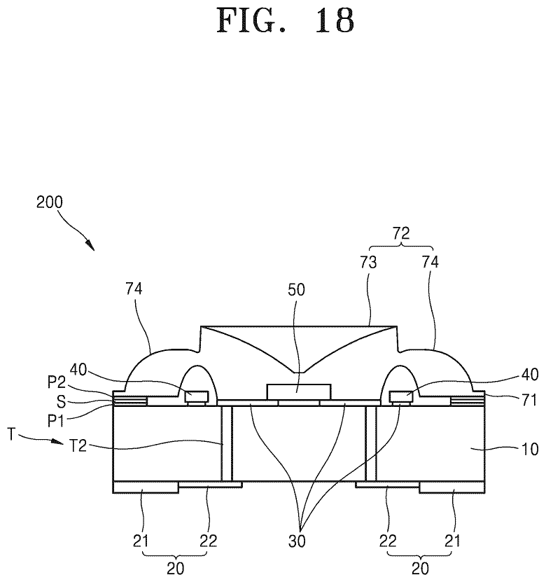

FIG. 16 is an exploded perspective view showing a wide coverage light-emitting drive package 200 according to some other embodiments of the present disclosure, FIG. 17 is a plan view showing the wide coverage light-emitting drive package 200 of FIG. 16, and FIG. 18 is a cross-sectional view showing the wide coverage light-emitting drive package 200 of FIG. 16.

As shown in FIGS. 16 to 18, a substrate pad P1 of metallic material is formed on at least a portion of the substrate 10 of the wide coverage light-emitting drive package 200 according to some other embodiments of the present disclosure, a lens pad P2 of metallic material is formed on at least a portion of the wide coverage diffusing lens 70, and a solder member S can be formed between the substrate pad P1 and the lens pad P2 so that the substrate pad P1 and the lens pad P2 can be metal bonded.

Here, the substrate pad P1 can be made of the same material as the wiring layer 30 and can be formed together when the wiring layer 30 is formed.

Also, the lens pad P2 can be formed by insert injection molding during lens molding, and the solder member S can be formed in various ways such as reflowing solder paste applied between the substrate pad P1 and the lens pad P2.

Also, the substrate pad P1 and the lens pad P2 can be disposed in cruciform patterns between the light-emitting devices 40. However, the positions or arrangement forms of the substrate pad P1 and the lens pad P2 can be applied in various forms.

Therefore, thermal conductivity and heat dissipation performance can be improved when high temperatures occur so that electrical reliability and durability of products can be improved, and rigidity can be increased by metal bonding methods so that strength and mechanical reliability of products can be significantly improved.

The present disclosure has been described with reference to the embodiments shown in the drawings, but these are merely exemplary, and those skilled in the art will understand that various modifications and equivalent other embodiments are possible therefrom. Therefore, the true technical protection scope of the present disclosure should be determined by the technical spirit of the appended claims.

What is claimed is:

1. A wide coverage diffusing lens, comprising:
an incident surface adapted to receive light generated from a light-emitting device; and
an exit surface adapted to refract or reflect the light incident from the incident surface and emit the light to a widely diffused area,
wherein the exit surface comprises:
a central column portion formed with an overall cylindrical shape; and
at least one rim dome portion formed integrally with the central column portion and disposed around a periphery of the central column portion, wherein at least a portion of the at least one rim dome portion is formed in a dome shape or a hemispherical shape.

2. The wide coverage diffusing lens of claim 1, wherein the central column portion comprises an outer peripheral surface formed on a side surface thereof and a central concave groove portion formed on a top surface thereof.

3. The wide coverage diffusing lens of claim 2, wherein the central concave groove portion comprises:
a central bottom portion formed concavely along a central axis; and
a central convex inclined surface portion formed to be inclined overall in a funnel shape toward the central bottom portion, wherein a cross-section of the central convex inclined surface portion is formed to be convex upwardly.

4. The wide coverage diffusing lens of claim 1, wherein the rim dome portion comprises a spherical surface formed on at least a portion of a side surface thereof and a rim concave groove portion formed concavely on the outer peripheral surface of the central column portion or on a top surface adjacent to the outer peripheral surface.

5. The wide coverage diffusing lens of claim 4, wherein the rim concave groove portion comprises:
a rim bottom portion formed on a top surface; and
a rim convex inclined surface portion formed to be inclined overall in a funnel shape toward the rim bottom portion, wherein a cross-section of the rim convex inclined surface portion is formed to be convex upwardly.

6. The wide coverage diffusing lens of claim 1, wherein the incident surface comprises:
a bottom portion formed overall in a flat shape; and
an incident groove portion formed concavely on the bottom portion to correspond to the light-emitting device and formed overall in a dome shape toward an apex portion.

7. The wide coverage diffusing lens of claim 1, wherein four rim dome portions are formed around a periphery of the central column portion to correspond to four light-emitting devices so that light can be dispersed overall into a rectangular area.

8. The wide coverage diffusing lens of claim 1, wherein two rim dome portions are formed around a periphery of the central column portion to correspond to two light-emitting devices so that light can be dispersed overall into a linear area.

9. The wide coverage diffusing lens of claim 1, wherein three rim dome portions are formed around a periphery of the central column portion to correspond to three light-emitting devices so that light can be dispersed overall into a triangular area.

10. A wide coverage light-emitting drive package comprising:
a substrate;
a terminal layer formed on a surface of the substrate;
a wiring layer formed on another surface of the substrate and electrically connected to the terminal layer through a through-electrode;
at least one light-emitting device mounted on a portion of the wiring layer and disposed at an outer position of the substrate;
a driver IC mounted on another portion of the wiring layer, disposed at a central position of the substrate, and adapted to drive the light-emitting device; and
a wide coverage diffusing lens adapted to diffuse light generated from the light-emitting device,
wherein the wide coverage diffusing lens comprises:
an incident surface adapted to receive light generated from the light-emitting device; and
an exit surface adapted to refract or reflect the light incident from the incident surface and emit the light to a widely diffused area,
wherein the exit surface comprises:
a central column portion formed with an overall cylindrical shape; and
at least one rim dome portion formed integrally with the central column portion and disposed around a periphery of the central column portion, wherein at least a portion of the at least one rim dome portion is formed in a dome shape or a hemispherical shape.

11. The wide coverage light-emitting drive package of claim 10, wherein the light-emitting device comprises a plurality of the light-emitting devices which are symmetrically disposed along diagonal or cruciform patterns centered around the driver IC to achieve wide coverage of optical paths.

12. The wide coverage light-emitting drive package of claim 10, wherein the light-emitting device comprises two or more LEDs disposed in front-left, front-right, rear-left, and rear-right directions respectively, or disposed in front, rear, left, and right directions respectively, with respect to the driver IC.

13. The wide coverage light-emitting drive package of claim 10, wherein the light-emitting device comprises at least one of a red LED, a green LED, a blue LED, a white LED, and combinations thereof.

14. The wide coverage light-emitting drive package of claim 10, wherein the light-emitting device is a micro-LED or a mini-LED, and the driver IC is a driver IC of one or more channels adapted to drive the micro-LED.

15. The wide coverage light-emitting drive package of claim 10, wherein:
a substrate pad of metallic material is formed on at least a portion of the substrate;
a lens pad of metallic material is formed on at least a portion of the wide coverage diffusing lens; and
a solder member is formed between the substrate pad and the lens pad so that the substrate pad and the lens pad can be metal bonded.
